(19) United States
(12) Patent Application Publication
(10) Pub. No.: US 2015/0049262 A1
(43) Pub. Date: Feb. 19, 2015

(54) FLEXIBLE TOUCH PANEL STUCTURE AND ELECTRONIC WATCH USING THE SAME

(71) Applicant: HON HAI PRECISION INDUSTRY CO., LTD., New Taipei (TW)

(72) Inventor: KUANG-YAO LIAO, New Taipei (TW)

(21) Appl. No.: 14/457,315

(22) Filed: Aug. 12, 2014

(30) Foreign Application Priority Data
Aug. 19, 2013 (TW) 102129616

(51) Int. Cl. G06F 1/16; H01M 6/40; G04G 21/08; H01M 10/04; G06F 3/041; H05K 1/02

(52) U.S. Cl. CPC G06F 1/1643; G06F 3/041; G06F 1/1652; G06F 1/163; H05K 1/028; G04G 21/08; H01M 10/0436; H01M 6/40; G06F 2203/04102; H01M 2220/30
USPC 349/12

(57) ABSTRACT

A flexible touch panel structure includes a thin-film battery and a touch module which are flexible. The thin-film battery includes a cathode connecting layer, a cathode layer, an electrolyte layer, an anode layer, flexible printed circuit (FPC) connecting layer and a ground layer electrically connected in that order. The thin-film battery further includes a connecting layer at a side of the cathode layer, the electrolyte layer, and the anode layer. The cathode connecting layer is electrically connected to FPC connecting layer via the connecting layer. The FPC connecting layer is equipped with connecting pins electrically connected to the anode layer and cathode connecting layer. The touch module includes a FPC touch signal layer and a FPC touch pad layer connected to the FPC touch signal layer. The present further discloses an electronic watch using the same.

### FIELD

The subject matter herein generally relates to a flexible touch panel structure and an electronic watch using the same.

### BACKGROUND

Flexible touch panels are widely used in electronic products. For example, a flexible touch panel can be assembled in an electronic watch. In a conventional process of assembling the electronic watch, a flexible touch panel, a circuit electrically coupled to the flexible touch panel, and a thin-film battery are provided respectively and then assembled in the electronic watch.

### BRIEF DESCRIPTION OF THE DRAWINGS

Implementations of the present technology will now be described, by way of example only, with reference to the attached figures.

FIG. 1 is a perspective view of an embodiment of an electronic watch.

FIG. 2 is a partial cross-sectional view of a flexible touch panel structure in the electronic watch of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

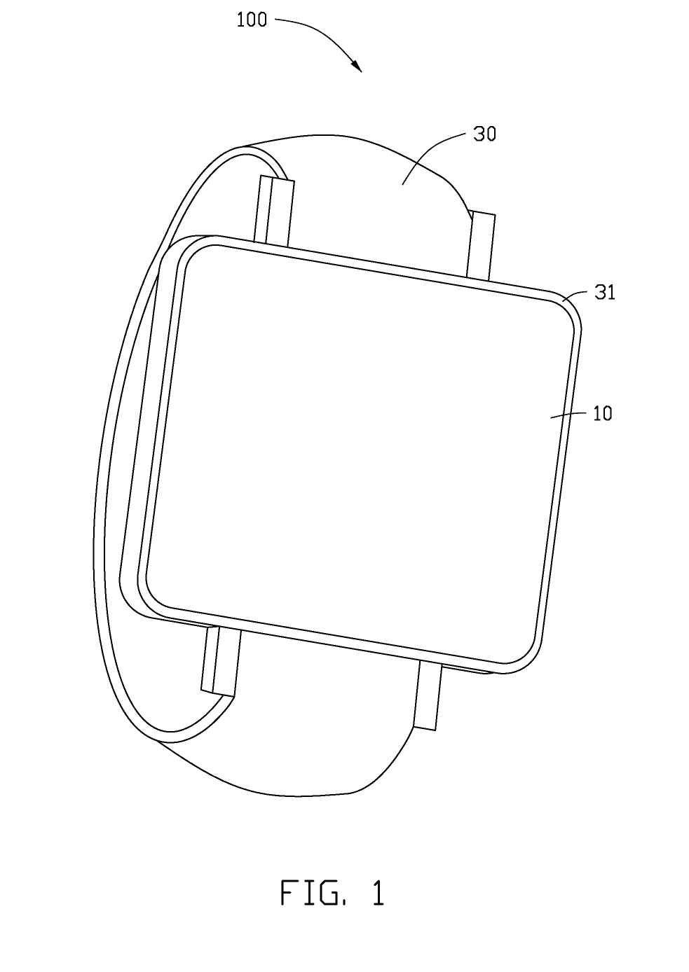

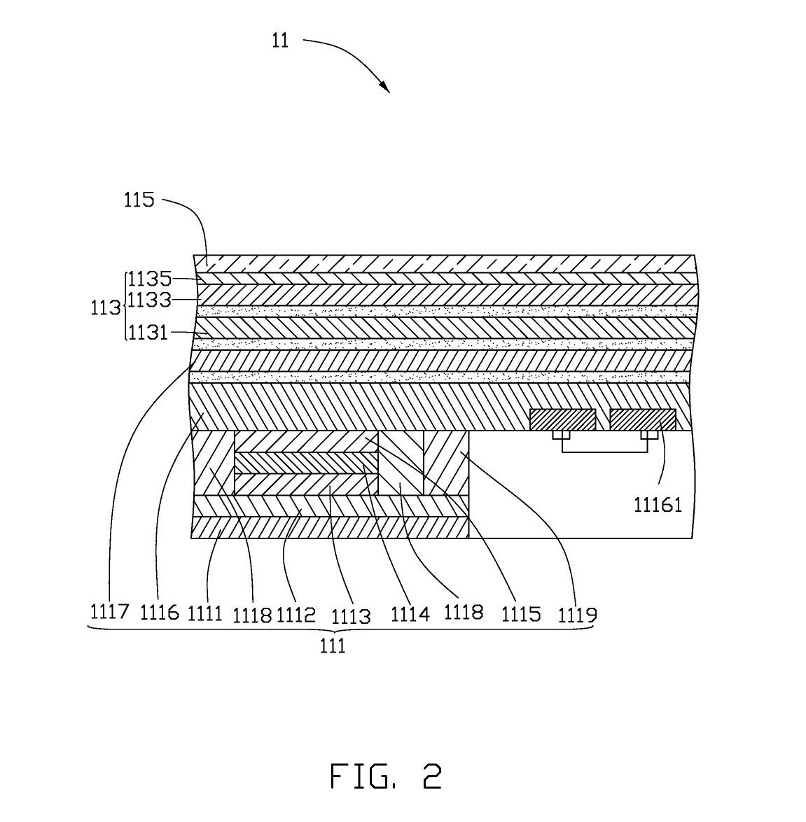

FIG. 1 illustrates an electronic watch 100 including a dial 10 and a band 30. The band 30 can include an assembly portion 31, and the dial 10 can be arranged in the assembly portion 31. The dial 10 can include a flexible touch panel structure 11 (see FIG. 2), a microprocessor, a memory-chip, and other elements (not shown). The assembly portion 31 can be a flexible soft plastic frame. The flexible touch structure 11 can also be used in jewelries, medicinal clothes comprising a display, and other electronic products.

FIG. 2 illustrates the flexible touch structure 11 including a thin-film battery 111, a touch module 113, and a display module 115. The flexible touch structure 11 can be installed in the assembly portion 31. The touch module 113 can be sandwiched between the thin-film battery 111 and the display module 115. The display module 115 can be attached to the bottom of the dial 10 as shown in FIG. 1. In the embodiment, all the thin-film battery 111, the touch module 113 and display module 115 can be flexible.

The thin-film battery 111 can include an encapsulation layer 1111, a cathode connecting layer 1112, a cathode layer 1113, an electrolyte layer 1114, an anode layer 1115, an FPC (Flexible Printed Circuit) connecting layer 1116, and a ground layer 1117 stacked in order. The encapsulation layer 1111 can be formed in the bottom of the assembly portion 31. An area of the cathode connecting layer 1112 can be substantially equal to an area of the encapsulation layer 1111. The cathode layer 1113, the electrolyte layer 1114, and the anode layer 1115 can have a substantially same area smaller than the area of the cathode connecting layer 1112.

The thin-film battery 111 can further include a sealing layer 1118 and a connecting layer 1119. The sealing layer 1118 can be substantially annular and positioned around the cathode layer 1113, the electrolyte layer 1114 and the anode layer 1115 stacked in order. The top and bottom ends of the sealing layer 1118 can be in tight contact with the FPC connecting layer 1116 and the cathode connecting layer 1112. The connecting layer 1119 can be positioned on one side of the sealing layer 1118. The two ends of the connecting layer 1119 can be electrically connected to the cathode connecting layer 1112 and the FPC connecting layer 1116, and the potential of the cathode connecting layer 1112 can be fed into the FPC connecting layer 1116. The anode layer 1115 can be electrically coupled to the FPC connecting layer 1116, and the potential of the anode layer 1115 can be fed into the FPC connecting layer 1116. One end of the FPC connecting layer 1116 can extend out of the connecting layer 1119 and equipped with electric pins 11161 electrically coupled to the anode layer 1115 and the cathode connecting layer 1112. The ground layer 1117 and the FPC connecting layer 1116 can be separated by a prepreg layer (not labeled).

The touch module 113 can include a FPC touch signal layer 1131 and a FPC touch pad layer 1133. The flexible touch panel structure 11 can further include a solder mask layer 1135 on the top of the FPC touch pad layer 1133. Areas of the FPC touch signal layer 1131, the FPC touch pad layer 1133, and the solder mask layer 1135 can be substantially equal to that of the ground layer 1117. The FPC touch signal layer 1131 can be laminated on the ground layer 1117 with a prepreg layer (not labeled) interposed therebetween. The FPC touch pad layer 1133 can be laminated on the FPC touch signal layer 1131 with a prepreg layer (not labeled) interposed therebetween. The FPC connecting layer 1116, the ground layer 1117, the FPC touch signal layer 1131, and the FPC touch pad layer 1133 are electrically coupled by wires (not shown).

The display module 115 can cover the solder mask layer 1135, used to display images. The display module 115 can be exposed to outside of the assembly portion 31.

In operation, the thin-film battery 111 can supply power to the flexible touch structure 11 by the electric pins 11161, the FPC touch signal layer 1131 can be electrically connected to the FPC touch pad layer 1133, and the display module 115 can display images, such as time, date, and other informations.

In other embodiments, the FPC touch signal layer 1131 can be positioned on one side of the FPC connecting layer 1116, and the flexible structure 11 can be more thinner.

In at least one embodiment, as the FPC connecting layer 1116, the ground layer 1117, the FPC touch signal layer 1131, and the FPC touch pad layer 1133 can be formed in one multilayer FPC and made in one process, the flexible touch structure 11 and the electronic watch 100 can be thin, and the flexibility can be increased.

The embodiments shown and described above are only examples. Many details are often found in the art such as the other features of a flexible touch panel structure and an electronic watch. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, comprising in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A flexible touch panel structure, comprising:
a thin-film battery comprising:
in stacked order, a cathode connecting layer, a cathode layer, an electrolyte layer, an anode layer, a flexible printed circuit connecting layer, and a ground layer; and
a connecting layer electrically coupling the cathode connecting layer and the flexible printed circuit connecting layer,
the flexible printed circuit connecting layer including connecting pins that electrically couple the anode layer and cathode connecting layer; and
a touch module positioned adjacent to the thin-film battery, the touch module comprising:
a flexible printed circuit touch signal layer; and
a flexible printed circuit touch pad layer electrically coupled to the flexible printed circuit touch signal layer,
the thin-film battery and the touch module together being structurally flexible.

2. The flexible touch panel structure as claimed in claim 1, wherein the flexible touch panel structure further comprises a display module on top of the touch module.

3. The flexible touch panel structure as claimed in claim 1, wherein the flexible printed circuit touch signal layer is positioned at a side of the ground layer away from the flexible printed circuit connecting layer, and the flexible printed circuit touch pad layer is positioned at a side of the flexible printed circuit touch signal layer away from the ground layer.

4. The flexible touch panel structure as claimed in claim 1, wherein the thin-film battery further comprises an encapsulation layer positioned at a side of the cathode connecting layer away from the cathode layer.

5. The flexible touch panel structure as claimed in claim 4, wherein an area of the cathode connecting layer is substantially equal to an area of the encapsulation layer; the cathode layer, the electrolyte layer, and the anode layer have a substantially same area smaller than that of the cathode connecting layer.

6. The flexible touch panel structure as claimed in claim 1, wherein the touch module further comprises a solder mask layer on top of the flexible printed circuit touch pad layer.

7. The flexible touch panel structure as claimed in claim 1, wherein the thin-film battery further comprises a sealing layer around the cathode layer, the electrolyte layer, and the anode layer; the sealing layer is substantially annular, and an top end and a bottom end of the sealing layer are in tight contact with the flexible printed circuit connecting layer and the cathode connecting layer.

8. The flexible touch panel structure as claimed in claim 7, wherein the connecting layer is positioned at a side of the sealing layer, and the two ends of the connecting layer are electrically coupled to the cathode connecting layer and the flexible printed circuit connecting layer to feed the potential of the cathode layer to the flexible printed circuit connecting layer; the anode layer is electrically coupled to the flexible printed circuit connecting layer to feed the potential of the anode layer to the flexible printed circuit connecting layer.

9. The flexible touch panel structure as claimed in claim 8, wherein the flexible printed circuit connecting layer, the ground layer, the flexible printed circuit touch signal layer, and the flexible printed circuit touch pad layer are electrically coupled.

10. An electronic watch, comprising:
a band comprising a flexible assembly portion; and
a dial assembled in the assembly portion, and having a flexible touch panel structure;
wherein, the flexible touch panel structure comprises:
a thin-film battery comprising a cathode connecting layer, a cathode layer, an electrolyte layer, an anode layer, flexible printed circuit connecting layer and a ground layer stacked in order: and
a connecting layer positioned at a side of the cathode layer, the electrolyte layer, and the anode layer;
the cathode connecting layer is electrically coupled to the flexible printed circuit connecting layer via the connecting layer;
the flexible printed circuit connecting layer is equipped with connecting pins electrically coupled to the anode layer and cathode connecting layer; and
a touch module comprises a flexible printed circuit touch signal layer and a flexible printed circuit touch pad layer electrically coupled to the flexible printed circuit touch signal layer;
wherein, the touch module is positioned at a side of the flexible printed circuit connecting layer;
wherein, the thin-film battery and the touch module are flexible;
wherein, the cathode connecting layer is positioned at the bottom of the assembly portion.

11. The electronic watch as claimed in claim 10, wherein the flexible touch panel structure further comprises a display module on top of the touch module.

12. The electronic watch as claimed in claim 10, wherein the flexible printed circuit touch signal layer is positioned at a side of the ground layer away from the flexible printed circuit connecting layer, and the flexible printed circuit touch pad layer is positioned at a side of the flexible printed circuit touch signal layer away from the ground layer.

13. The electronic watch as claimed in claim 10, wherein the thin-film battery further comprises an encapsulation layer positioned at a side of the cathode connecting layer away from the cathode layer.

14. The electronic watch as claimed in claim 10, wherein the touch module further comprises a solder mask layer on top of the flexible printed circuit touch pad layer.
